(19) United States
(12) Patent Application Publication
(10) Pub. No.: US 2008/0137290 A1
(43) Pub. Date: Jun. 12, 2008

(54) Large-Sized Power Supply Device

(76) Inventors: Noriko Tanaka, Osaka (JP); Hideaki Fujita, Osaka (JP)

Correspondence Address: MCDERMOTT WILL & EMERY LLP, 600 13TH STREET, NW, WASHINGTON, DC, 20005-3096, US

(21) Appl. No.: 11/793,204

(22) PCT Filed: Apr. 6, 2006
(86) PCT No.: PCT/JP2006/307308

§ 371 Date: Jun. 18, 2007

(30) Foreign Application Priority Data
Apr. 13, 2005 (JP) 2005-115313

(51) Int. Cl. H05K 7/20

(52) U.S. Cl. 361/690; 361/704

(57) ABSTRACT

A large-sized power supply device including: a plurality of lithium ion secondary batteries including sealed battery cases and safety valves, the sealed battery cases containing a positive electrode, a negative electrode, a porous heat-resistant layer placed between the positive and negative electrodes, and a non-aqueous electrolyte, and the safety valves being provided on the sealed battery cases and operating at a predetermined pressure; and a battery container in which the plurality of lithium ion secondary batteries are housed. The power supply device is improved in safety, generates substantially no gas and, therefore, does not require any special exhaust hose for discharging gas. Thus, a large-sized power supply device having a markedly high volume efficiency can be provided.

### TECHNICAL FIELD

The present invention relates to a large-sized power supply device including a plurality of lithium ion secondary batteries connected in series. More particularly, the present invention relates to a large-sized power supply device for mobile use such as use in hybrid motor vehicles, electric motor vehicles or electric motorcycles, or to a fixed large-sized power supply, e.g., a home-use power supply for a power load leveling purpose or the like, or a backup power supply.

### BACKGROUND ART

Lithium ion secondary batteries generally have a high energy density and enable apparatuses to be reduced in size and weight. Therefore the development of them in various fields is being pursued. There are expectations for it in the field of large-sized power supply devices for mobile use and the field of fixed large-sized power supply devices in particular.

With respect to the field of large-sized power supply devices for mobile use, strong and mild hybrid motor vehicles having an internal combustion engine and a motor or a fuel cell and a motor for motive power and electric motor vehicles and electric motorcycles using a motor for motive power may be mentioned.

With respect to the field of fixed large-sized power supply devices, backup use in the event of power failure, elevator drive use, and home use for power station load leveling by charging nighttime power and by supplying necessary power during the daytime may be mentioned.

For mobile use for example, a power supply device for conventional hybrid motor vehicles is constructed by housing a plurality of unit batteries (a battery group) in one battery container. The battery container is placed in a spatial portion formed separately from a comportment space. Cooling piping connected to the comportment space is provided on the battery container to efficiently cool the unit batteries. A special exhaust hose is also provided for the purpose of discharging a gas generated from the battery in the event of abnormality to the outside of the vehicle. The exhaust hose is isolated from the spatial portion in the battery container and communicate with the interior of the unit battery through a safety valve. Conventionally, nickel-metal hydride batteries are used as the battery group mainly for reasons in terms of battery performance and safety.

The performance of a battery is largely influenced by environmental temperature. If high input/output is related as in a hybrid motor vehicle, the battery temperature is increased by Joule heat thereby generated to badly affect the battery life characteristics. Therefore, cooling in the battery container in particular is indispensable for use in electric motor vehicles.

Ordinarily, the compartment space in a vehicle is maintained in a certain temperature range during running of the vehicle. It is, therefore, possible to efficiently cool the battery by causing air in the compartment space to flow into the battery container. To achieve this function, the compartment space and the interior of the battery container are connected by a cooling air pipe.

When the internal pressure of the battery is increased by generation of a gas in the battery, the safety valve operates to discharge the gas into the battery container. The special exhaust hose is provided in the battery container for the purpose of preventing the gas from flowing into the compartment space. The gas is discharged from the exhaust hose to the outside of the vehicle. The generated gas is thereby prevented from flowing to the compartment space through the cooling air piping, thus ensuring safety (see, for example, Patent Documents 1 and 2).

On the other hand, hybrid motor vehicles incorporating lithium ion secondary batteries in place of nickel-metal hydride batteries to have an increased output have been energetically studied and developed. The danger of gas generation in the event of overcharge or internal short-circuit in lithium ion secondary batteries is higher than that in nickel-metal hydride batteries. In many cases of consumer-oriented power supply devices, a gas vent hole is also provided (see, for example, Patent Document 3).

For example, as a fixed type of large power supply device, a home-use large-sized power supply device capable of load leveling may be mentioned. This power supply device is supposed to be placed outdoors, and there is a need for a temperature control mechanism for controlling the temperature of a battery by taking in outside air and a route for discharge of gas generated from the battery in the event of abnormality. If the generated gas is directly discharged without being controlled, the possibility arises of an influence on peripheral equipment, flowing of the gas into the house, a bad influence of residents and people living in surrounding houses, and so on. There is, therefore, a need to control discharge of the generated gas to a safe place via a special exhaust route.

Patent Document 1: Japanese Laid-Open Patent Publication No. 2001-110377

Patent Document 2: Japanese Laid-Open Patent Publication No. 2004-039582

Patent Document 3: Japanese Laid-Open Utility Model publication No. 05-065054

### DISCLOSURE OF THE INVENTION

### Problem To be Solved by the Invention

The exhaust mechanism in the above-described conventional mobile power supply devices for mobile use such as use in electric motor vehicles has, for safety in the event of abnormality such as gas generation, a special exhaust hose for reliably discharging a gas generated from a battery to the outside of the vehicle while preventing the gas from the power supply device into the compartment through the cooling air piping, and has a considerably low volume efficiency.

Also in a fixed home-use large-sized power supply device, as described above, if the generated gas is directly discharged without being controlled, the possibility arises of an influence on peripheral equipment, flowing of the gas into the house, a bad influence of residents and people living in surrounding houses, and so on. A need then arises to lead the generated gas to a safe place such as a tank via a special exhaust route and to accumulate the gas in the safe place, resulting in failure to make full use of the volume efficiency specific to lithium ion batteries.

Also, since the danger of gas generation in the event of overcharge or internal short-circuit in lithium ion secondary batteries is higher than that in nickel-metal hydride batteries, a gas generated from a large-sized power supply device used by connecting a multiplicity of batteries in series cannot be sufficiently controlled by taking a mere measure based on providing a consumer-oriented simple gas vent hole in the power supply device, and commercialization of the power supply device cannot be expected.

In actuality, in a case where a power supply device using a lithium ion secondary battery in an electric motor vehicle, there is a need to provide a special exhaust hose having a higher exhaust capacity and therefore requiring a larger space in comparison with a case where a nickel-metal hydride battery, which means a further reduction in volume efficiency.

### Means for Solving the Problem

A large-sized power supply device of the present invention has:

a plurality of lithium ion secondary batteries including sealed battery cases and safety valves,

the sealed battery cases containing a positive electrode, a negative electrode, a porous heat-resistant layer placed between the positive and negative electrodes, and a non-aqueous electrolyte, and

the safety valves being provided on the sealed battery cases and operating at a predetermined pressure; and

a battery container in which the plurality of lithium ion secondary batteries are housed.

Preferably, the battery container has an exhaust port.

Preferably, the exhaust port has an opening area large enough to maintain the pressure in the battery container lower than the pressure at which the safety valve operates.

In a preferred embodiment of the present invention, the porous heat-resistant layer comprises at least one porous heat-resistant layer including an inorganic oxide filler.

In another preferred embodiment of the present invention, the at least one porous heat-resistant layer contains a heat-resistant resin having a thermal deformation temperature of 200° C. or higher.

In a still another preferred embodiment of the present invention, the power supply device further includes a shutdown layer placed between the positive and negative electrodes, the shutdown layer is formed of a porous film of a thermoplastic resin, and the shutdown temperature is 80 to 180° C.

In a further preferred embodiment of the present invention, the battery container has an inlet and an outlet for cooling air, and a spatial portion which communicates with the inlet and outlet, and through which cooling air for cooling the lithium ion secondary batteries flows.

### EFFECT OF THE INVENTION

In the lithium ion secondary battery of the present invention, a porous heat-resistant layer is provided between the positive and negative electrodes. Therefore, substantially no amount of gas is discharged and an improvement in safety can be achieved. Even in a case where fumes are generated in a power supply device for an electric motor vehicle for example and leak into the interior of the vehicle compartment, the amount of fumes is such that only a slight offensive smell is felt. Therefore, it is not necessary to provide any special exhaust hose; the volume efficiency is increased; and a large reduction in cost can be achieved.

### BRIEF DESCRIPTION OF THE DRAWINGS

FIG. 1 is a perspective view showing an example of a power supply device according to an embodiment of the present invention mounted on vehicle body, an essential portion being shown in section.

FIG. 2 is a perspective view of a lithium ion secondary battery constituting the power supply device shown in FIG. 1.

### BEST MODE FOR CARRYING OUT THE INVENTION

Embodiments of the present invention will be described with reference to the accompanying drawings for understanding of the present invention. The embodiments described below are an example of implementation of the present invention, and the present invention is not limited to the embodiments.

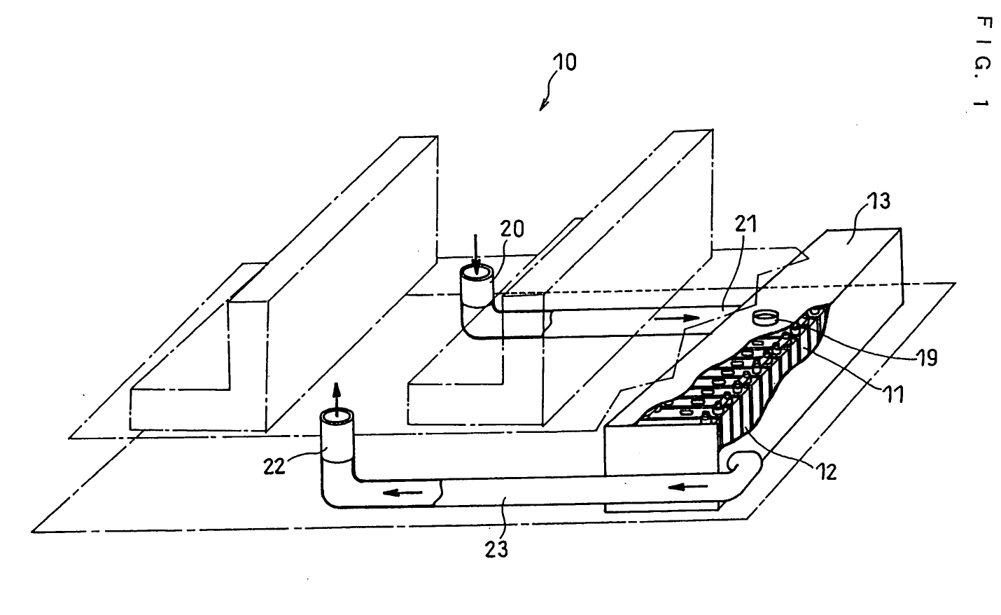

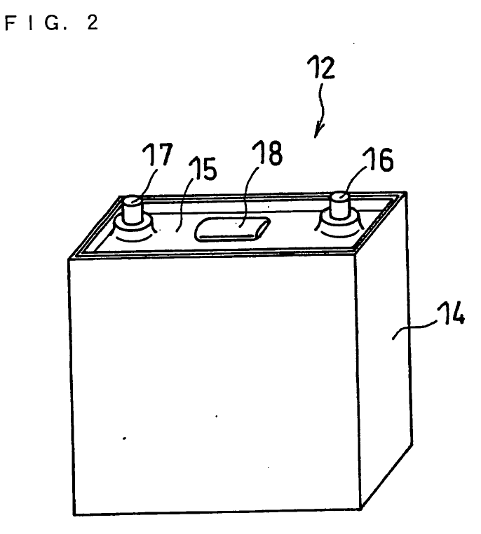

FIG. 1 shows an example of a power supply device in accordance with the present invention provided on a vehicle body. FIG. 2 shows a lithium ion secondary battery.

This power supply device 10 is constituted by a battery group 11 formed by connecting a plurality of lithium ion secondary batteries 12 in series and a battery container 13 which is made of a resin and in which the battery group 11 is housed. In the lithium ion secondary battery 12, as shown in FIG. 2, power generating elements are enclosed by a rectangular battery case 14 made of a metal, e.g., stainless steel, and a sealing plate 15 which closes an opening portion of the battery case 14 and which is made of a metal, e.g., stainless steel. A positive terminal 16 and a negative terminal 17 are provided on the sealing plate 15 while being insulated from the same. The positive terminal and the negative terminal of each adjacent pair of batteries 12 are connected in series by a piece of connecting metal. The sealing plate is joined to the opening portion of the battery case by resistance welding. A safety valve which operates to open when the pressure in the battery increases to a predetermined value is provided in the sealing plate 15. As the safety valve, a known one for use in a lithium ion secondary battery may be used.

A spatial portion for circulation of cooling air for cooling each battery 12 is provided in the battery container 13. One end of the spatial portion communicates with a pipe 21 having an air inlet 20 opened in a vehicle compartment. The other end of the spatial portion communicates with a pipe 23 having an air outlet 22 opened in the vehicle compartment. A fan (not shown) is provided in the pipe 21. When the power supply device supplies electric power to the fan, the fan operates to blast air in the vehicle compartment into the battery container 13, thereby cooling the batteries 12. The air having its temperature increased during cooling of the batteries is returned to the vehicle compartment via the pipe 23. An exhaust port 19 is provided in an upper portion of the battery container 13. Through this exhaust port, mainly when the above-described fan is stopped, a gas discharged into the space inside the battery container by the operation of the safety valve of some of the batteries 12 is discharged out of the battery container 13. Therefore the opening area of the exhaust port 19 is large enough to prevent the pressure in the battery container from being increased by such a generated gas to a level at which the other safety valves of the batteries operate. However, substantially no gas is generated from the battery of the present invention, as described below, and, therefore, it is not necessary to make the exhaust port 19 so large.

The example described here is an example of mounting on a vehicle and high input/output is frequently repeated. Therefore cooling air is introduced into the battery container. In the case of use where the frequency with which input/output is repeated is not so high, there is no need for the pipes 21 and 23 and, even in the event of gas generation in some of the batteries, there is no possibility of the safety valves of the other batteries operating, if the exhaust port 19 is provided.

The power generating elements of the lithium ion secondary battery used in the present invention are a positive electrode, a negative electrode and a non-aqueous electrolyte. Further, a porous heat-resistant layer is interposed between the positive and negative electrodes.

A method of directly forming the porous heat-resistant layer on battery constituent elements or a method of forming the porous heat-resistant layer as a film in advance and thereafter incorporating as a battery constituent element may be adopted. The method of directly forming the porous heat-resistant layer on battery constituent elements comprises a method in which the porous heat-resistant layer is formed on one surface or both surfaces of the positive electrode, the negative electrode or a separator. The porous heat-resistant layer may be formed both on the surface of the positive electrode and on the surface of the negative electrode. Further, the same effect can also be obtained by forming the porous heat-resistant layer both on the electrode and on the separator. On the other hand, in a case where the porous heat-resistant layer is formed as a film in advance and thereafter incorporated as a battery constituent element, the porous heat-resistant layer may be inserted between the positive electrode and the separator or between the negative electrode and the separator.

Further, the porous heat-resistant layer may have a separator function, that is; the porous heat-resistant layer may be used as a separator.

Preferably, the porous heat-resistant layer is formed of a porous film including an insulating filler, particularly an inorganic oxide filler and a binder. It is preferable to select, for example, as the inorganic oxide filler, an inorganic porous material such as alumina, zeolite, silicon nitride, silicon carbide, titanium oxide, zirconium oxide, magnesium oxide, zinc oxide or silicon dioxide, which does not react in side reaction badly influencing the battery characteristics under the presence of a non-aqueous electrolyte and under the oxidation reduction potential at the use of battery, which is chemically stable, and which has a high purity.

The porous heat-resistant layer may be formed of a heat-resistant resin. Preferably, such a resin and a heat-resistant resin used as a binder for the inorganic oxide filler have a thermal deformation temperature (a load-deflection temperature at 1.82 MPa in test method ASTM-D648) of 200° C. or higher. Such a resin is, for example, polyimide, polyamideimide, aramid, polyphenylene sulfide, polyether imide, polyethylene terephthalate, polyether nitril, polyether ether ketone or polybenzoimidazole.

Preferably, the lithium ion secondary battery used in the present invention has a shutdown layer between the positive and negative electrodes apart from the porous heat-resistant layer. Preferably, this shutdown layer is formed of a porous film of a thermoplastic resin and the shutdown temperature at which it becomes a substantially non-porous layer is 80 to 180° C. More specifically, from the viewpoint of resistance to organic solvent and hydrophobicity, an olefin resin such as polypropylene or polyethylene in a single state or a combination of them may be used.

A plurality of the above-described lithium ion secondary batteries are connected in series to form a group battery. The group battery may be of, for example, 20×3.6 V×5 Ah=0.36 kWh or more if it has a series connection of 20 cells in the case of use in a motor bicycle for mobile use. The group battery may be of about 60×3.6 V×5 Ah=1.08 kWh or more if it has a series connection of 60 cells in the case of use in a hybrid motor vehicle. The group battery can also be adapted to use in a large bus or truck by further combining series/parallel connections. Also, a home-use power supply device in fixed use can be adapted by combining series/parallel connections and can be formed as a power supply device of about 20 kWh.

Air is taken in from the cooling air inlet 20 to cool the battery group 11. Various sensors, controllers and so on may be incorporated as required in the battery container 13 in which the battery group 11 is housed. The material of the battery container 13 may be a metal, a resin or a lamination. It may alternatively be formed of a member having both a metal layer and a resin layer.

In ordinary cases, generation of a gas can occur in the lithium ion secondary battery in the event of internal short-circuit or overcharge. Of these, overcharge is a problem soluble by combining one or several operations including control by monitoring the battery voltage. In hybrid motor vehicles, the occurrence of the overcharge problem is relatively lower because the battery is used at an SOC lower than 80%. On the other hand, the controller cannot sufficiently deal with internal short circuit. Conventionally, an exhaust hose or the like for releasing generated gas is provided to cope with the problem in addition to measures for single batteries.

In the battery group 11 formed of lithium ion secondary batteries in accordance with the present invention, even when heat generated by internal short-circuit, the increase in scale of short-circuit can be limited by the porous heat-resistant layer (high-heat-resistance porous film) to prevent thermal runaway and the generation of a substantial amount of gas. Therefore, there is no need to provide a special exhaust hose and the provision of the exhaust hole 19 according to need may suffice. If the exhaust hole 19 is provided, an opening area may be set by considering the volume efficiency such that the pressure in the pack is limited so as not to exceed the opening valve pressure of the safety valves for the single batteries. If the pressure in the pack exceeds the valve opening pressure of the safety valves for the single batteries due to generation of gas in the event of abnormality, the valves for the batteries other than the single batteries where the gas has been generated are inwardly opened to cause liquid leakage. Therefore such excessive pressure is undesirable.

Examples of the present invention will be described below.

### EXAMPLE 1

A lithium-nickel composite oxide expressed by a composition formula LiNi_{0.7}Co_{0.2}Al_{0.1}O₂ was used as a positive electrode active material. Cobalt sulfate and aluminum sulfate were added in predetermined proportions to and dissolved in a NiSO₄ aqueous solution. To this aqueous solution, a sodium hydroxide aqueous solution was slowly added dropwise with agitating to accomplish neutralization, thereby producing a precipitate of nickel hydroxide Ni_{0.7}Co_{0.2}Al_{0.1}(OH)₂ including Co and Al. This precipitate was filtered, washed with water, dried at 80° C. The average particle size of nickel hydroxide thereby obtained was 10 μm.

The above-described nickel hydroxide was heat-treated in atmospheric air at 900° C. for 10 hours to obtain nickel oxide Ni_{0.7}Co_{0.2}Al_{0.1}O. It was confirmed by powder X-ray diffraction that the obtained oxide was single-phase nickel oxide.

Subsequently, lithium hydroxide 1-hydrate was added to the above-described nickel oxide so that the sum of the numbers of Ni, Co and Al atoms was equal to the number of Li atoms. This mixture was heat-treated in dry air at 800° C. for 10 hours to obtain target LiNi_{0.7}Co_{0.2}Al_{0.1}O₂. It was confirmed by powder X-ray diffraction that the obtained lithium-nickel composite oxide had single-phase hexagonal-system layered structure and is a solid solution containing Co and Al.

The above-described lithium-nickel composite oxide was pulverized and classified to obtain a positive electrode active material powder having an average particle size of 9.5 μm and a specific surface area by the BET method of 0.5 m²/g. Acetylene black provided as a conductive agent and polyvinylidene fluoride (PVdF) provided as a binder (KF polymer #1320, a product from KUREHA CORPORATION) were mixed in solid-content proportions of 90:5:6 by weight, and N-methyl-2-pyrrolidone (hereinafter referred to as “NMP”) was further added, followed by kneading. A positive electrode mixture paste was thereby made. This mixture paste was applied on both sides of a 15 μm-thick aluminum foil positive electrode current collector so as to provide a 6 mm-wide continuous aluminum foil exposed portion on one end portion along the longer side, dried, rolled and slit-worked, thus making a positive electrode plate having a thickness of 0.078 mm, a width of 118 mm (the mixture layer width: 112 mm) and a length of 3090 mm.

A negative electrode plate was made as described below.

First, artificial graphite provided as an active material, an aqueous dispersion of SBR provided as a binder and carboxymethyl cellulose (CMC) provided as a thickener were mixed in solid-component proportions of 96:3:1 by weight, and the same weight of water as that of the weight of the above solid materials was further added, followed by kneading. A negative electrode mixture paste was thereby made. This paste was applied on both sides of a 10 μm-thick copper foil so as to provide a 10 mm-wide continuous copper foil exposed portion on one end portion along the longer side, dried, rolled and slit-worked, thus making a negative electrode plate having a thickness of 0.077 mm, a width of 127 mm (the mixture layer width: 117 mm) and a length of 3306 mm.

The above-described positive and negative electrode plates were dried in a drying furnace in atmospheric-air at 100° C. for 10 hours and then at 80° C. for 10 hours for the purpose of removing a remaining water content.

Next, porous heat-resistant layers were formed on both sides of the negative electrode plate, as described below. First, α-alumina particles and a binder were mixed in proportions of 97:3 by weight, and a dispersion medium of N-methyl-2-pyrrolidone (hereinafter referred to as “NMP”) was added to this mixture, followed by kneading. A paste for the porous heat-resistant layer was thereby made. As the binder, a main binder formed of polyether sulfone and a sub binder formed of polyvinylpyrrolidone were used in proportions of 2:1 by weight. This binder was applied to both sides of the negative electrode plate and dried. The thickness of the obtained porous heat-resistant layer on one surface was 25 μm.

The negative electrode plate on which the above-described porous heat-resistant layer was formed was wound together with the above-described positive electrode plate to make an electrode group having a generally rectangular transverse section. A positive electrode current collector terminal was laser-welded to an exposed portion of the positive electrode current collector in this electrode group, and a negative electrode current collector terminal was resistance-welded to an exposed portion of the negative electrode current collector. This electrode group was inserted in a rectangular battery case made of a metal. A positive terminal and a negative terminal insulated from each other were attached to a metallic sealing plate joined by welding to the opening portion of the battery case. A safety valve was provided in the sealing plate. The safety valve operates when the pressure in the battery increases to a predetermined value. The safety valve is formed of a metal thin film.

Next, ethylene carbonate (EC), diethyl carbonate (DEC) and ethyl methyl carbonate (DMC) were mixed in proportions of 20:40:40 by weight to obtain a mixture solvent, and one mol/liter of LiPF₆ was dissolved in the mixture solvent, thereby preparing an electrolyte. This electrolyte was poured into the battery case through a liquid inlet provided in the sealing plate and the liquid inlet was sealed, thus making a lithium ion secondary battery having a nominal capacity of 5 Ah. The valve opening pressure of the exhaust valve of a battery was set to 6.5 kgf/cm². Sixty batteries thus produced were connected in series to form a battery group, which was inserted in a battery container made of a resin without an exhaust port, thus making a battery pack having a power capacity of 1.08 kWh. The volume of the space between the inner walls of the battery container and the battery group, which is filled with gas, was 1070 cm³.

### EXAMPLE 2

A battery pack was made in the same manner as Example 1 except that the thickness of a porous heat-resistant layer formed on both sides of a negative electrode plate was set to 5 μm, and that a 20 μm-thick polyethylene-polypropylene composite film (2300, a product from Celgard Inc. (shutdown temperature: 120° C.)) was inserted as a shutdown layer between the positive and negative electrode plates.

### EXAMPLE 3

A battery pack was made in the same manner as Example 1 except that a 25 μm-thick porous heat-resistant layer was provided on both sides of a positive electrode plate instead of being provided on both sides of a negative electrode plate.

### EXAMPLE 4

A battery pack was made in the same manner as Example 1 except that a 5 μm-thick porous heat-resistant layer was formed on both sides of a positive electrode plate, and that a 20 μm-thick polyethylene-polypropylene composite film (2300, a product from Celgard Inc. (shutdown temperature: 120° C.)) was inserted as a shutdown layer between the positive and negative electrode plates.

### EXAMPLE 5

A battery pack was made in the same manner as Example 1 except that a 2.5 μm-thick porous heat-resistant layer was formed on both sides of each of positive and negative electrode plates, and that a 20 μm-thick polyethylene-polypropylene composite film (2300, a product from Celgard Inc. (shutdown temperature: 120° C.)) was inserted as a shutdown layer between the positive and negative electrode plates.

### EXAMPLE 6

A battery pack was made in the same manner as Example 2 except that no porous heat-resistant layer was formed on any surface of a negative electrode plate, and that a 5 μm-thick porous heat-resistant layer was formed on a surface of the 20 μm-thick polyethylene-polypropylene composite film used in Example 2, by applying a paste for the porous heat-resistant layer to the surface.

### EXAMPLE 7

In this example, an aramid resin was used for the porous heat-resistant layer. The aramid resin (KEVLAR, a product from DU PONT-TORAY CO., LTD. (3 mm cut fiber, having a load-deflection temperature (thermal deformation temperature) exceeding 320° C. in test method ASTM-D648 (1.82 MPa)) was uniformly dissolved in NMP at 80° C., and a lithium chloride powder (a product from KANTO CHEMICAL CO., INC.) was added to the solution and dissolved by being sufficiently agitated. The proportions of the aramid resin, the lithium chloride powder and NMP were 20:1:80 by weight. The NMP solution containing the aramid and lithium chloride was applied with a 100 μm-thick gap by a bar coater to a 20 μm-thick polyethylene-polypropylene composite film (2300, a product from Celgard Inc. (shutdown temperature: 120° C.)) heated at 60° C., and dried in a drying furnace at 110° C. for 3 hours, thereby obtaining on the composite film a white aramid resin film containing lithium chloride. This film was immersed in a distilled water hot bath at 60° C. for 2 hours to dissolve and remove the solid-stage lithium chloride contained in the aramid resin film. The film was thereafter washed with pure water. A 25 μm-thick porous film formed of the composite film and the aramid resin film was obtained in this way. A battery pack was made in the same manner as Comparative Example 1 except that this porous film was inserted between positive and negative electrode plates.

### EXAMPLE 8

In this example, a porous heat-resistant layer formed of an aramid resin and an inorganic oxide filler was used. 200 parts by weight of fine particle alumina was added to 100 parts by weight (solid) of the NMP solution obtained in Example 7, the solution containing the aramid resin and lithium chloride. By using this dispersion, a film formed of the aramid resin and alumina particles was formed on a 20 μm-thick polyethylene-polypropylene composite film (2300, a product from Celgard Inc. (shutdown temperature: 120° C.)), as is the corresponding film in Example 7. A battery pack was made in the same manner as Example 7 except that a 25 μm-thick porous film thus obtained was inserted between positive and negative electrode plates.

### EXAMPLE 9

A battery pack was made in the same manner as Example 7 except that a copolymer of trifluorochloroethylene and polyvinylidene fluoride having a thermal deformation temperature of 200° C. or less was used in place of the aramid resin.

### EXAMPLE 10

By using the NMP solution containing the aramid and lithium chloride in Example 7, an aramid resin film was formed on a 15 μm-thick polyethylene-polypropylene composite film (2300, a product from Celgard Inc.). A battery pack was made in the same manner as Example 2 except that a 20 μm-thick porous film thus obtained was used in place of the shutdown layer.

### EXAMPLE 11

A battery pack was made in the same manner as Example 10 except that a 5 μm-thick porous heat-resistant layer was provided on both sides of a positive electrode plate instead of providing a porous heat-resistant layer on both sides of a negative electrode plate.

### EXAMPLE 12

A battery pack was made in the same manner as Example 10 except that a 2.5 μm-thick porous heat-resistant layer was formed on both sides of each of positive and negative electrode plates.

### EXAMPLE 13

The length of a positive electrode plate was set to 6180 mm, the length of a negative electrode plate was set to 6612 mm, and 60 cells of a lithium ion secondary battery having a nominal capacity of 10 Ah were connected in series, thereby making a battery group having a power capacity of 2.16 kWh. Also, the volume of the space in the battery container that is filled with gas was set to 1070 cm³. A battery pack was made in the same manner as Example 1 except for the above.

### EXAMPLE 14

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 1 except for the above.

### EXAMPLE 15

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 2 except for the above.

### EXAMPLE 16

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 3 except for the above.

### EXAMPLE 17

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 4 except for the above.

### EXAMPLE 18

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 5 except for the above.

### EXAMPLE 19

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 6 except for the above.

### EXAMPLE 20

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 7 except for the above.

### EXAMPLE 21

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 8 except for the above.

### EXAMPLE 22

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm was provided. A battery pack was made in the same manner as Example 9 except for the above.

### EXAMPLE 23

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 10 except for the above.

### EXAMPLE 24

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 11 except for the above.

### EXAMPLE 25

The length of a positive electrode plate was set to 6180 mm, the length of a negative electrode plate was set to 6612 mm, and a lithium ion secondary battery having a nominal capacity of 10 Ah was used. The volume of the space in the battery container that is filled with gas was set to 1070 cm³. An exhaust hole having an opening area of 5 mm² was provided. A battery pack was made in the same manner as Example 12 except for the above.

### COMPARATIVE EXAMPLE 1

A battery pack was made in the same manner as Example 1 except that no porous heat-resistant layer is provided.

### COMPARATIVE EXAMPLE 2

A battery pack was made in the same manner as Comparative Example 1 except that the battery group was inserted in a battery container in which the opening area of an exhaust hole was 5 mm².

### COMPARATIVE EXAMPLE 3

A battery pack was made in the same manner as Comparative Example 1 except that the battery group was inserted in a battery container in which the opening area of an exhaust hole was 30 mm².

Evaluations were made on the above-described battery packs.

A nail penetration test was conducted as a test using a condition assumed to be short-circuit in one battery in the battery pack. A single battery nail penetration test was first made. Each battery was charged to an upper limit of 4.2 V with a constat current value of 0.2C with respect to the nominal capacity of the battery, and was thereafter discharged to a lower limit of 3.0 V with the constat current value. The discharge capacity obtained at this time was assumed to be SOC 100%. Constant-current charging from the 3.0 V discharged state to SOC 80% was thereafter performed. The single battery after discharge was inserted in a pressuretight sealed container provided with a pressure sensor, and an iron round nail having a diameter of 2.7 mm was pierced through the single battery in a 25° C. environment at a speed of 180 mm/sec. The internal pressure in the sealed container at this time was measured. From this internal pressure, the amount of gas generation and the gas generation rate were computed. Further, the pressure in the battery container was computed from the total amount of generated gas and the volume of the space in the battery container.

A battery pack nail penetration test was next made. The battery group in which 60 cells are connected in series was inserted in the battery container, and an iron round nail having a diameter of 2.7 mm was allowed to penetrate at a speed of 180 mm/sec into one battery cell positioned at an end of the battery group, and the states of the batteries other than that was penetrated with the nail were observed. A state where no change was observed was indicated by ◯, and a state in which the exhaust valve was opened and liquid leakage occurred was indicated by x. Table 1 shows the results.

TABLE 1

| | | | Battery | |
|---|---|---|---|---|
| | | Total | container | Battery |
| | Maximum gas | amount of | internal | pack nail |
| | generation | generated | pressure | penetra- |
| | rate | gas | computed value | tion test |
| | (cm³/sec) | (cm³) | (kgf/cm²) | result |
| Ex. 1 | 3600 | 2680 | 3.5 | ∘ |
| Ex. 2 | 3450 | 1810 | 2.7 | ∘ |
| Ex. 3 | 3670 | 2620 | 3.4 | ∘ |
| Ex. 4 | 3460 | 1920 | 2.8 | ∘ |
| Ex. 5 | 3440 | 1800 | 2.7 | ∘ |
| Ex. 6 | 3500 | 1970 | 2.8 | ∘ |
| Ex. 7 | 3270 | 2040 | 2.9 | ∘ |
| Ex. 8 | 2410 | 1570 | 2.5 | ∘ |
| Ex. 9 | 4070 | 2900 | 3.7 | ∘ |
| Ex. 10 | 1910 | 1090 | 2.0 | ∘ |
| Ex. 11 | 1970 | 1150 | 2.1 | ∘ |
| Ex. 12 | 1890 | 1100 | 2.0 | ∘ |
| Ex. 13 | 7280 | 5760 | 6.4 | ∘ |
| Ex. 14 | 7280 | 5760 | 6.4 | ∘ |
| Ex. 15 | 7100 | 3890 | 4.6 | ∘ |
| Ex. 16 | 7500 | 5640 | 6.3 | ∘ |
| Ex. 17 | 7090 | 4140 | 4.9 | ∘ |
| Ex. 18 | 7110 | 3870 | 4.6 | ∘ |
| Ex. 19 | 7170 | 4230 | 5.0 | ∘ |
| Ex. 20 | 6710 | 4400 | 5.1 | ∘ |
| Ex. 21 | 6780 | 3380 | 4.2 | ∘ |
| Ex. 22 | 8340 | 6240 | 6.8 | ∘ |
| Ex. 23 | 3910 | 2340 | 3.2 | ∘ |
| Ex. 24 | 4040 | 2490 | 3.3 | ∘ |
| Ex. 25 | 3960 | 2360 | 3.2 | ∘ |
| Com. Ex. 1 | 79000 | 70000 | 66.4 | x |
| Com. Ex. 2 | 79000 | 70000 | 66.4 | x |
| Com. Ex. 3 | 79000 | 70000 | 66.4 | ∘ |

In Comparative Example 1 in which no porous heat-resistant layer is provided between the positive and negative electrodes, each of the maximum gas generation rate and the total amount of generated gas in the single battery nail penetration test is considerably high and there is a possibility of generated gas flowing into the vehicle compartment. This is because the temperatures in the battery and the battery container are increased by Joule heat at the time of short-circuit to cause thermal shrinkage of the separator and, hence, expansion of the short-circuit portion, and because the temperatures are thereby further increased to increase the amount of generated gas. In the battery containers with no exhaust holes, the battery container internal pressure becomes considerably high to increase the risk of liquid leakage by the operation of the battery safety valve, deformation of the battery by pressure and malfunctions of the various sensors and the controller.

In the nail penetration test on the battery pack in Comparative Example 1, the pressure in the battery pack was increased by the generation of gas from the battery penetrated with the nail, and the safety valves for the single batteries other than the battery penetrated with the nail are operated by the external pressure, resulting in occurrence of liquid leakage from the single batteries.

In Comparative Example 2, generated gas was not sufficiently discharged through the opening area of 5 mm² of the exhaust hole, and the results were the same as those of Comparative Example 1.

In Comparative Example 3, since the opening area of the exhaust hole was 30 mm², the pressure in the battery pack did not exceed the valve opening pressure of the battery safety valves, and no liquid leakage was recognized. In Comparative Examples 1 to 3, however, a large amount of gas was generated in comparison with Examples. There is, therefore, a need to provide an exhaust hose or the like for safely discharging the gas to avoid any bad influence on surroundings.

In each of the battery packs in Examples 1 to 12 having one or more porous heat-resistant layers between the positive and negative electrodes, each of the maximum gas generation rate and the total amount of generated gas in the single battery nail penetration test was low and the computed value of the battery container internal pressure was limited below the exhaust valve opening pressure. Thus, in Examples, since at least one porous heat-resistant layer was provided between the positive and negative electrodes, the short-circuit portion was not expanded even though the temperature was increased at the time of short-circuit, thus limiting the gas generation.

From the results of Examples 1 to 6 using the porous heat-resistant layer containing an inorganic oxide filler, the following is apparent. That is, forming the porous heat-resistant layer on one of or both of the negative and positive electrode or on the shutdown layer is effective and concurrent use of the porous heat-resistant layer and the shutdown layer ensures a further improvement in the effect.

From the results of Examples 7 and 8, an effect in the case of using the aramid resin having a heat resistance temperature of 320° C. or higher for the porous heat-resistant layer was confirmed and a further improvement in the effect can be achieved by mixing the alumina filler in the aramid resin.

The thermal deformation temperature of the heat-resistant copolymer of trifluorochloroethylene and polyvinylidene fluoride used in Example 9 is 160° C., higher than the thermal deformation temperature about 60 to 100° C. of polyolefin system resin ordinarily used as a separator. Accordingly, the gas generation in Example 9 was reduced in comparison with Comparative Example 1, and certain effectiveness of Example 9 was confirmed. However, it can be understood that the amount of generated gas in Example 9 is larger than that in Example 7.

From the results of Examples 10 to 12, it can be understood that the effect of limiting the amount of generated gas can be maximized by providing both the inorganic oxide filler and the heat-resistant resin as the porous heat-resistant layer, and the shutdown layer.

The results of the nail penetration test on the battery packs in Examples 1 to 12 are such that there were no changes in the safety valves for the batteries other than the battery penetrated with the nail even though no exhaust hole was provided in the battery container, and no liquid leakage was recognized.

In the Examples 13 to 25 larger in power capacity (Wh) than that of Examples 1 to 12, each of the maximum gas generation rate and the total amount of generated gas in the single battery nail penetration test was increased relative to that in Examples 1 to 12 and the computed value of the battery container internal pressure due to generated gas was increased. This may be because the mass of active material and the amount of electrolyte contained in the battery in Examples 1 to 12 are larger than that of Examples 13 to 25, and because the amount of electrolyte evaporated by Joule heat generated by short-circuit current in the nail penetration test was increased.

In Example 13, no exhaust hole was provided in the battery container and, accordingly, the computed value of the battery container internal pressure was 6.4 kg/cm², close to the valve opening pressure (6.5 kg/cm²) of the battery safety valve. If the battery container internal pressure exceeds the valve opening pressure of the battery safety valve, there is a possibility of the safety valves of the batteries other than the short-circuited battery being opened to cause liquid leakage. Therefore such excessive pressure is undesirable. In Examples 14 to 25, therefore, an exhaust hole having an opening area of 5 mm² was provided to discharge generated gas. The results of the nail penetration test on the battery packs in Examples 14 to 25 are such that there were no changes in the safety valves for the batteries other than the battery penetrated with the nail, and no liquid leakage was recognized. It can be understood that the exhaust hole may be provided as required according to conditions including the power capacity, a battery safety valve design and the volume of the space in the battery container.

In the examples of the present invention, as described above, at least one porous heat-resistant layer is provided between the positive and negative electrodes and, therefore, each of the maximum gas generation rate and the total amount of generated gas at the time of short-circuit is low and it is not necessary to provide an exhaust hole in the battery container. Even in a case where an exhaust hole is required, an exhaust hole having a restricted opening area may suffice for gas discharge. Thus, the volume efficiency is increased and a large reduction in cost can be achieved.

### INDUSTRIAL APPLICABILITY

In the large-sized power supply device in accordance with the present invention, substantially no amount of gas is discharged even when a local internal short-circuit occurs, so that an improvement in safety can be achieved. Even in the event of fuming, fuming is no more than an offensive smell and it is not necessary to provide any special exhaust hose. Therefore the volume efficiency is increased and a large reduction in cost can be achieved. Accordingly, the present invention is useful as a large-sized power supply device for mobile use such as use in hybrid motor vehicles, electric motor vehicles or electric motorcycles, or as a large-sized power supply device for fixed use such as home use, backup use or elevator use.

1. A large-sized power supply device comprising:
a plurality of lithium ion secondary batteries including sealed battery cases and safety valves,
said sealed battery cases containing a positive electrode, a negative electrode, a porous heat-resistant layer placed between said positive and negative electrodes, and a non-aqueous electrolyte, and
said safety valves being provided on said sealed battery cases and operating at a predetermined pressure; and
a battery container in which said plurality of lithium ion secondary batteries are housed.

2. The large-sized power supply device according to claim 1, wherein the battery container has an exhaust port.

3. The large-sized power supply device according to claim 2, wherein the exhaust port has an opening area large enough to maintain the pressure in the battery container lower than the pressure at which the safety valve operates.

4. The large-sized power supply device according to claim 1, wherein the porous heat-resistant layer comprises at least one porous heat-resistant layer including an inorganic oxide filler.

5. The large-sized power supply device according to claim 1, wherein the at least one porous heat-resistant layer contains a heat-resistant resin having a thermal deformation temperature of 200° C. or higher.

6. The large-sized power supply device according to claim 1, further comprising a shutdown layer placed between the positive and negative electrodes, wherein the shutdown layer is formed of a porous film of a thermoplastic resin and the shutdown temperature is 80 to 180° C.

7. The large-sized power supply device according to claim 1, wherein the battery container has an inlet and an outlet for cooling air, and a spatial portion which communicates with the inlet and outlet, and through which cooling air for cooling the lithium ion secondary batteries flows.
